(19) United States
(12) Patent Application Publication
(10) Pub. No.: US 2013/0120925 A1
(43) Pub. Date: May 16, 2013

(54) MEMORY MODULE, BOARD ASSEMBLY AND MEMORY SYSTEM INCLUDING THE SAME, AND METHOD OF OPERATING THE MEMORY SYSTEM

(71) Applicant: Young-Jin Park, Incheon (KR)

(72) Inventor: Young-Jin Park, Incheon (KR)

(21) Appl. No.: 13/619,580

(22) Filed: Sep. 14, 2012

(30) Foreign Application Priority Data
Nov. 10, 2011 (KR) 10-2011-0116765

(51) Int. Cl. H05K 1/18; G06F 12/02

(52) U.S. Cl. 361/679.31; 711/102; 711/E12.007

(57) ABSTRACT

Example embodiments include a memory module having a first volatile memory, a second volatile memory, a nonvolatile memory, and a controller configured to control an operation of the second volatile memory, and an operation of the nonvolatile memory. When first write data received from an external controller are written to the first volatile memory in a write operation, the controller receives and writes the first write data to the second volatile memory. The controller is configured to perform backup and restore operations using a buffer, the nonvolatile memory, the first volatile memory, and/or the second volatile memory. Example embodiments include a memory module having a first nonvolatile memory, a second nonvolatile memory, and a third nonvolatile memory, with corresponding backup and restore features. Example embodiments also include methods for processing the data and operating the various components of the memory system.

### CROSS-REFERENCE TO RELATED APPLICATIONS

This application claims priority under 35 U.S.C. §119(a) to Korean Patent Application No. 10-2011-0116765 filed on Nov. 10, 2011, the entire contents of which are hereby incorporated by reference.

### BACKGROUND

Embodiments of the inventive concept relate to a memory module, and more particularly, to a memory module for backing up data stored in a main memory to a nonvolatile memory, a board assembly and memory system including the same, and a method of operating the memory system.

A central processing unit (CPU) included in a memory system, e.g., a computing system, reads data stored in a main memory, processes the data, and stores the processed data in the main memory.

However, when power supply to the memory system is abnormally cut off or the data stored in the main memory has errors, the memory system cannot operate normally.

When the main memory is implemented by volatile memory and the power supply to the memory system is cut off, data stored in the main memory is lost. When the main memory is implemented by nonvolatile memory and an error occurs in the data stored in the main memory, the data having the error is retained in the main memory. Accordingly, even when the memory system is rebooted, the error in the data cannot be corrected.

### SUMMARY

According to some embodiments of the inventive concept, there is provided a memory module including a first volatile memory, a second volatile memory, a nonvolatile memory, and a first controller configured to control an operation of the second volatile memory and to control an operation of the nonvolatile memory. When first write data received from a second external controller is written to the first volatile memory in a write operation, the first controller may receive and write the first write data to the second volatile memory.

The first write data may be stored in a first storage area of the first volatile memory and a second storage area of the second volatile memory. The first storage area is designated by a write address and the second storage area is designated by the same write address.

The first controller may back up the first write data stored in the second volatile memory to the nonvolatile memory.

The memory module may further include a buffer. The controller may store second write data output from the second external controller into the buffer while the first write data stored in the second volatile memory is backed up to the nonvolatile memory. After the backup is completed, the first controller may write the second write data stored in the buffer to the second volatile memory.

Each of the first and second volatile memories may be implemented by a dynamic random access memory (DRAM).

According to other embodiments of the inventive concept, there is provided a board assembly including the above-described memory module and a main board. The memory module may be connected to the main board through a slot provided in, e.g. built into, the main board.

The first write data may be stored in a first storage area of the first volatile memory and to a second storage area of the second volatile memory. The first storage area is designated by a write address and the second storage area is designated by the same write address.

According to further embodiments of the inventive concept, there is provided a memory system including the above-described board assembly and a processor configured to be mounted to the main board and to control an operation of the first volatile memory included in the memory module using the memory controller mounted to the main board.

The memory module may further include a buffer. The first controller may back up the first write data stored in the second volatile memory to the nonvolatile memory. The first controller may store second write data output from the external controller in the buffer while the first write data stored in the second volatile memory is backed up to the nonvolatile memory. After the backup is completed, the first controller may write the second write data stored in the buffer to the second volatile memory.

In other embodiments, a memory module includes a first nonvolatile memory and a second nonvolatile memory configured to process first data, a third nonvolatile memory configured to back up the first data, and a first controller configured to control a write operation of the second nonvolatile memory and the backup operation of the third nonvolatile memory. When first write data received from an external controller are written to the first nonvolatile memory in a write operation, the first controller may receive and write the first write data to the second nonvolatile memory.

The first controller may write the first write data written to the first nonvolatile memory and an address related to the first write data to the second nonvolatile memory.

The first controller may back up the first write data and the address, which are stored in the second nonvolatile memory, to the third nonvolatile memory. The first controller thereafter may erase the first write data and the address from the second nonvolatile memory.

The memory module may further include a buffer. The first controller may store second write data output from the second external controller in the buffer while the first write data and the address stored in the second nonvolatile memory are backed up to the third nonvolatile memory. After the backup is completed, the first controller may write the second write data stored in the buffer to the second nonvolatile memory.

In yet other embodiments, a method of operating a memory system includes writing write data to a first memory under the control of a memory controller, a controller writing the write data output from the memory controller to a second memory, the controller backing up the data written to the second memory to a third memory, and the controller restoring the data of the first memory based on the data backed up to the third memory when the memory system is rebooted.

Backing up the data may include the controller storing new data output from the memory controller in a buffer during the backup, and the controller writing the data stored in the buffer to the second memory after the backup.

### BRIEF DESCRIPTION OF THE DRAWINGS

The above and other features and advantages of example embodiments will become more apparent by describing in detail example embodiments thereof with reference to the attached drawings in which:

FIG. 1 is a block diagram of a memory system according to some embodiments of the inventive concept;

FIG. 2 is a diagram for explaining a write operation of the memory system illustrated in FIG. 1;

FIG. 3 is a diagram for explaining a backup operation of the memory system illustrated in FIG. 1;

FIG. 4 is a diagram of a memory map of a volatile memory according to some embodiments of the inventive concept;

FIG. 5 is a diagram for explaining a restore operation of the memory system illustrated in FIG. 1;

FIG. 6 is a block diagram of a memory system according to other embodiments of the inventive concept;

FIG. 7 is a diagram for explaining a write operation of the memory system illustrated in FIG. 6;

FIG. 8 is a diagram for explaining a backup operation of the memory system illustrated in FIG. 6;

FIG. 9 is a diagram for explaining a restore operation of the memory system illustrated in FIG. 6;

FIGS. 10A-10D are flowcharts of various techniques of operating the memory system illustrated in FIG. 1 or 6 according to some embodiments of the inventive concept;

FIG. 11 is a block diagram of a memory system according to further embodiments of the inventive concept; and

FIG. 12 is a block diagram of a memory system according to other embodiments of the inventive concept.

### DETAILED DESCRIPTION

Example embodiments now will be described more fully hereinafter with reference to the accompanying drawings, in which example embodiments are shown. Example embodiments may, however, be embodied in many different forms and should not be construed as limited to the embodiments set forth herein. Rather, these example embodiments are provided so that this disclosure will be thorough and complete, and will fully convey the scope of example embodiments to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

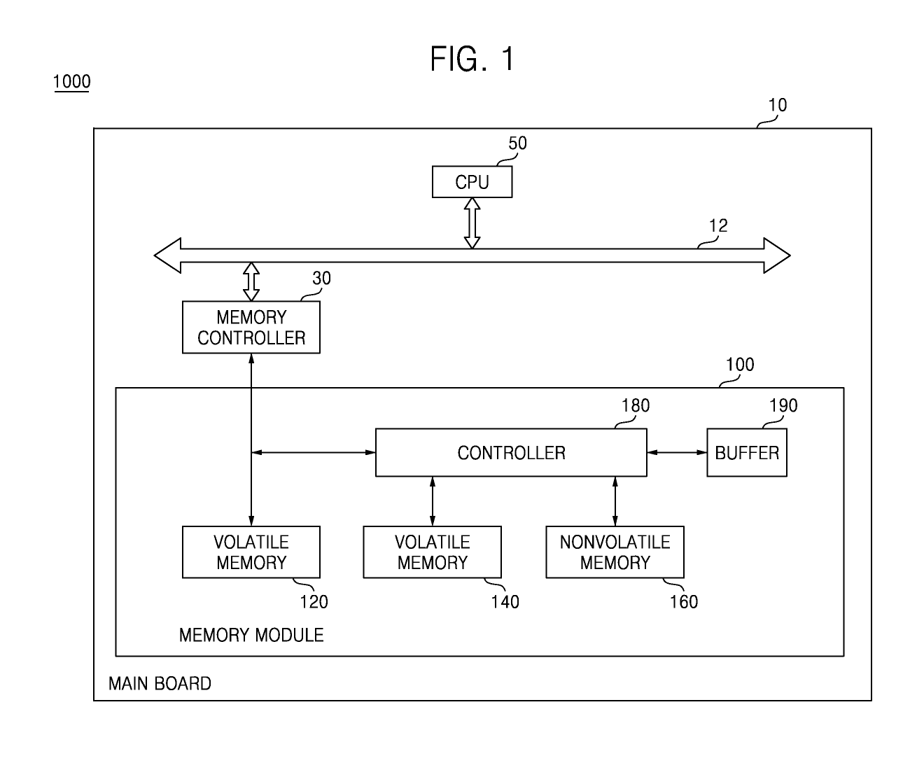

FIG. 1 is a block diagram of a memory system 1000 according to some embodiments of the inventive concept. The memory system 1000 includes a main board 10, a memory module 100, a memory controller 30, and a central processing unit (CPU) 50.

The memory system 1000 may be implemented as a personal computer (PC), a laptop computer, a data server, a network-attached storage (NAS), a portable device, and/or a computing system. The portable device may be a mobile telephone, a smart phone, a tablet PC, a personal digital assistant (PDA) and/or a portable multimedia player (PMP).

The memory controller 30 may be mounted to the main board 10. The memory controller 30 may control the operation of the memory module 100 under the control of the CPU 50. More specifically, in a write operation, the memory controller 30 may output a write command, a write address, and write data and write them in a certain memory area of the memory module 100, e.g., in a storage area of a first volatile memory 120.

In a read operation, the memory controller 30 may output a read command and a read address. The write address and/or the read address are addresses related to a storage area of the first volatile memory 120 included in the memory module 100.

The CPU 50 may be mounted to the main board 10 and may control the operation of the memory module 100 via the memory controller 30. The CPU 50 and the memory controller 30 may communicate with each other through a data/address/command bus 12.

The memory module 100 may be connected to the main board 10 via a slot or a memory socket provided in, e.g. built into, the main board 10.

The memory module 100 includes the first volatile memory 120, a second volatile memory 140, a nonvolatile memory 160, and a controller 180. According to some embodiments, the memory module 100 may also include a buffer 190.

The first volatile memory 120 included in the memory module 100 may be used as a main memory of the memory system 1000. In the write operation, the first volatile memory 120 may write the write data in the storage area corresponding to the write address based on the write command and the write address, which are provided by the memory controller 30. In the read operation, the first volatile memory 120 may read data from a storage area corresponding to the read address based on the read command and the read address, which are also provided by the memory controller 30.

Each of the first and second volatile memories 120 and 140, respectively, may be implemented by dynamic random access memory (DRAM), static RAM (SRAM), thyrister RAM (T-RAM), zero-capacitor RAM (Z-RAM), and/or twin transistor RAM (TTRAM), or the like. The second volatile memory 140 may have the same or similar characteristics as the first volatile memory 120. The second volatile memory 140 may be used as a supplementary memory to serve in the event that the performance of the first volatile memory 120 used as the main memory deteriorates.

For instance, when the first and second volatile memories 120 and 140 are implemented by the same types of memories, the access speed of the first volatile memory 120 may be the same or substantially the same as that of the second volatile memory 140. On the other hand, performance deterioration that may occur in the first volatile memory 120 when the first and second volatile memories 120 and 140 have substantially different access speeds can be prevented.

When the first and second volatile memories 120 and 140 are implemented by DRAM, the memory module 100 may be implemented by a single in-line memory module (SIMM), dual in-line memory module (DIMM), and/or small outline DIMM (SO-DIMM).

The nonvolatile memory 160 may be implemented by magnetic random access memory (MRAM), spin-transfer torque MRAM (STT-MRAM), resistive memory, phase-change RAM (PRAM), and/or flash memory, or the like. The flash memory may be divided into NOR flash memory and NAND flash memory.

The controller 180 may control the operations of the second volatile memory 140 and the nonvolatile memory 160. The controller 180 may also decode control signals provided by the memory controller 30. In the write operation, the controller 180 receives the write command, the write address, and the write data from the memory controller 30 and processes or decodes them. In addition, the controller 180 outputs the decoded write command to the second volatile memory 140.

The second volatile memory 140 may receive the write command, the write address, and the write data and may write the write data in the storage area corresponding to the write address. In addition, the controller 180 may decode a command provided from the memory controller 30 and may control a read operation or a write operation based on the command.

The address of the storage area of the first volatile memory 120 to which the write data are written is the same as the address of the storage area of the second volatile memory 140 to which the write data are written. The size of the first volatile memory 120 may be the same as or different from the size of the second volatile memory 140.

Accordingly, when data are written to the first volatile memory 120, the data are also written to the second volatile memory 140. The data stored in the second volatile memory 140 then are copied to the nonvolatile memory 160, which may be referred to as a “backup operation.”

In the backup operation, the controller 180 reads the data from the second volatile memory 140 and writes the read data to the nonvolatile memory 160. When new data are output from the memory controller 30 during the backup operation, the controller 180 may temporarily store the new data in the buffer 190 and, after the backup operation is completed, may write the data stored in the buffer 190 to the second volatile memory 140. For example, if the memory controller 30 causes new data to be written to the volatile memory 120 while the controller 180 is performing a backup operation of previously written data, then the controller 180 may temporarily store the new data in the buffer 190 until after the backup operation of the previously written data is completed, as further described in detail below. Thereafter, the controller 180 may write the data stored in the buffer 190 to the second volatile memory 140. Moreover, the controller 180 may also perform one or more subsequent backup operations, which may include, for example, reading the new data stored in the second volatile memory 140 and writing the new data to the nonvolatile memory 160.

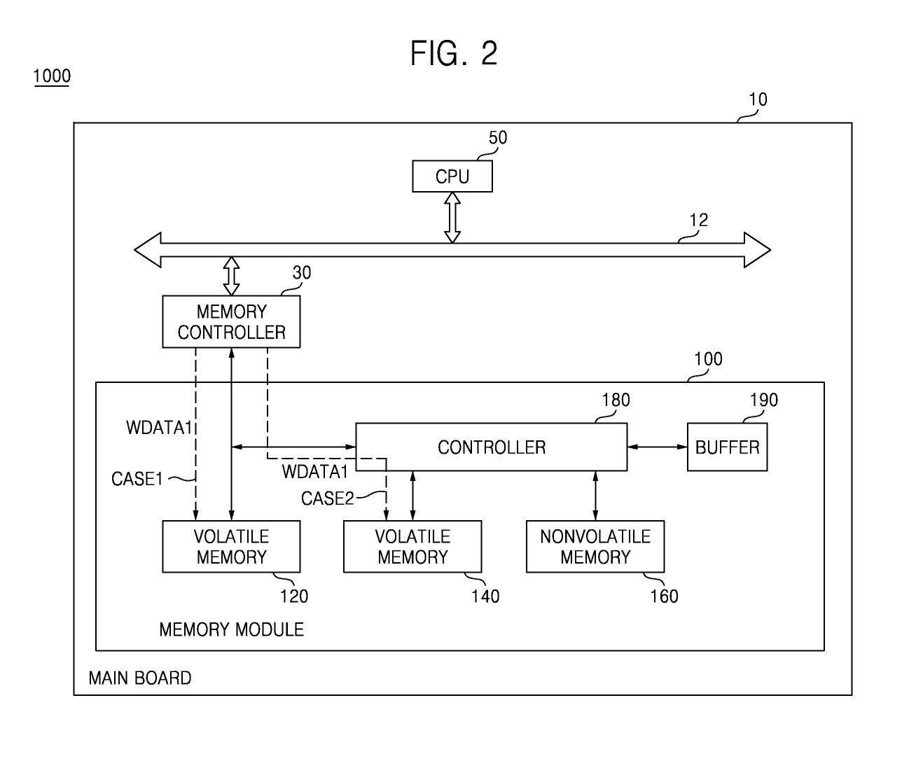

FIG. 2 is a diagram for explaining a write operation of the memory system 1000 illustrated in FIG. 1. Referring to FIG. 2, in the write operation, the memory controller 30 outputs a first write command, a first write address, and first write data WDATA1 under the control of the CPU 50.

The first volatile memory 120 may receive the first write command, the first write address, and the first write data WDATA1 from the memory controller 30 and write the first write data WDATA1 to a first storage area corresponding to the first write address (CASE1).

In addition, the controller 180 may receive the first write command, the first write address, and the first write data WDATA1 output from the memory controller 30 and may write the first write data WDATA1 to a second storage area of the second volatile memory 140 corresponding to the first write address (CASE2). The write operations associated with CASE1 and CASE2 may occur simultaneously or at about the same time.

The address of the first storage area is the same as the address of the second storage area. Accordingly, the first write data WDATA1 stored in the first volatile memory 120 is the same as the first write data WDATA1 stored in the second volatile memory 140.

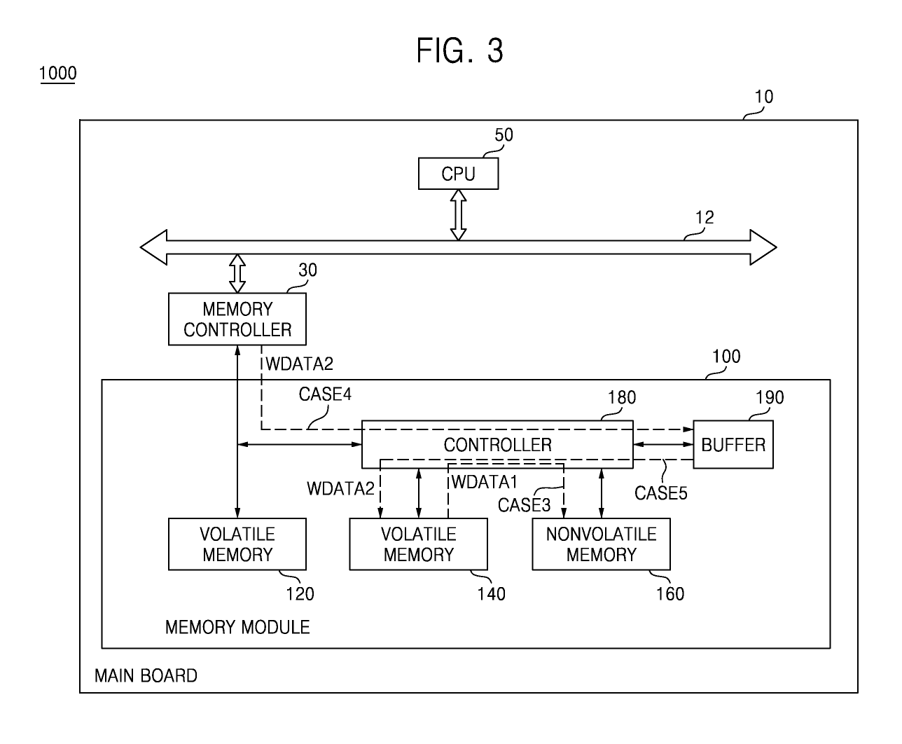

FIG. 3 is a diagram for explaining a backup operation of the memory system 1000 illustrated in FIG. 1. Referring to FIGS. 2 and 3, the controller 180 performs the backup operation in which the data WDATA1 stored in the second volatile memory 140 is backed up to the nonvolatile memory 160 (CASES). In other words, the first write data WDATA1 written to the second volatile memory 140 may be backed up to the nonvolatile memory 160 under the control of the controller 180. At this time, the controller 180 reads the first write data WDATA1 from the second volatile memory 140 and writes (i.e., re-writes) the first write data WDATA1 that has been read by the controller 180 to the nonvolatile memory 160.

The backup operation may be performed periodically. In other words, the controller 180 may perform the backup operation at predetermined time intervals.

Alternatively, the backup operation may be triggered by one or more events, such as by a write operation, a series of predetermined write operations, a read operation, a series of predetermined read operations, a message from the memory controller 30, or the like.

When a second write command, a second write address, and second write data WDATA2 are output from the memory controller 30 while the controller 180 is performing the backup operation, the first volatile memory 120 writes the second write data WDATA2 to a storage area corresponding to the second write address in response to the second write command.

Meanwhile, since the backup operation is in progress, the controller 180 cannot write the second write data WDATA2 to the second volatile memory 140. At this time, the controller 180 may store the second write command, the second write address, and the second write data WDATA2, which are output from the memory controller 30, in the buffer 190 (CASE4).

After finishing the backup operation, the controller 180 writes the second write data WDATA2 stored in the buffer 190 to the second volatile memory 140 (CASES). In other words, the second write data WDATA2 is written to the storage area corresponding to the second write address. In addition, the controller 180 can perform another backup operation similar to CASES, although with WDATA2 rather than WDATA1. In other words, the controller 180 can write the second write data WDATA2 stored in the volatile memory 140 to the nonvolatile memory 160 so that all or substantially all of the data stored in the volatile memory 140 are also stored in the nonvolatile memory 160.

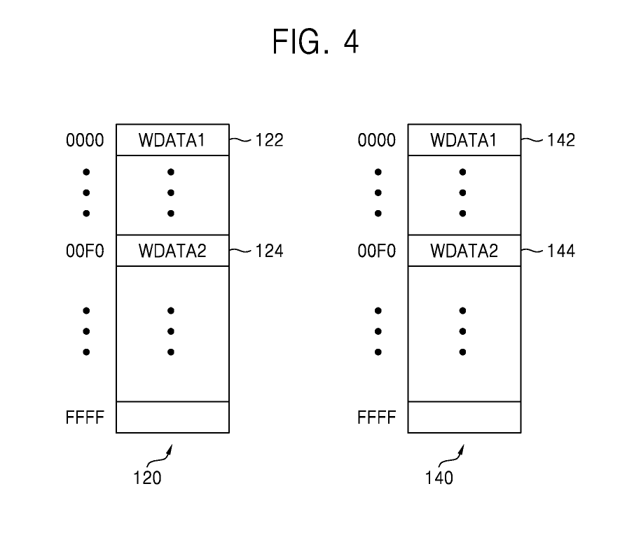

FIG. 4 is a diagram of a memory map of a volatile memory according to some embodiments of the inventive concept. FIG. 4 shows the memory maps of the first and second volatile memories 120 and 140, respectively, illustrated in FIG. 1.

Referring to FIGS. 1 through 4, addresses are allocated to storage areas, respectively, in the first volatile memory 120. For instance, the first volatile memory 120 may include a storage area to the start of which an address of “0000” (e.g., illustrated here as a hexadecimal number) is assigned and to the end of which an address of FFFF (e.g., illustrated here as a hexadecimal number) is assigned. Similarly, addresses are assigned to storage areas, respectively, in the second volatile memory 140. For instance, the second volatile memory 140 may include a storage area to the start of which an address of “0000” (e.g., illustrated here as a hexadecimal number) is assigned and to the end of which an address of FFFF (e.g., illustrated here as a hexadecimal number) is assigned.

When a first address output from the memory controller 30 is “0000”, the first write data WDATA1 is written to a first storage area 122 corresponding to the address “0000” in the first volatile memory 120. Similarly, the first write data WDATA1 is written to a second storage area 142 corresponding to the address “0000” in the second volatile memory 140. In other words, the address of the first storage area 122 to which the first write data WDATA1 is written in the first volatile memory 120 is the same as the address of the second storage area 142 to which the first write data WDATA1 is written in the second volatile memory 140.

When a second address output from the memory controller 30 is “00F0” (e.g., illustrated here as a hexadecimal number), the second write data WDATA2 is written to a third storage area 124 corresponding to the address “00F0” in the first volatile memory 120. Similarly, the second write data WDATA2 is written to a fourth storage area 144 corresponding to the address “00F0” in the second volatile memory 140. In other words, the address of the third storage area 124 to which the second write data WDATA2 is written in the first volatile memory 120 is the same as the address of the fourth storage area 144 to which the second write data WDATA2 is written in the second volatile memory 140.

Physical positions of respective storage areas storing the same data in the first and second volatile memories 120 and 140, respectively, may be the same or different from each other. It will also be understood that the hexadecimal addresses used in the example embodiment mentioned above are for illustrative purposes, and any suitable addresses can be used and still fall within the inventive concepts disclosed herein.

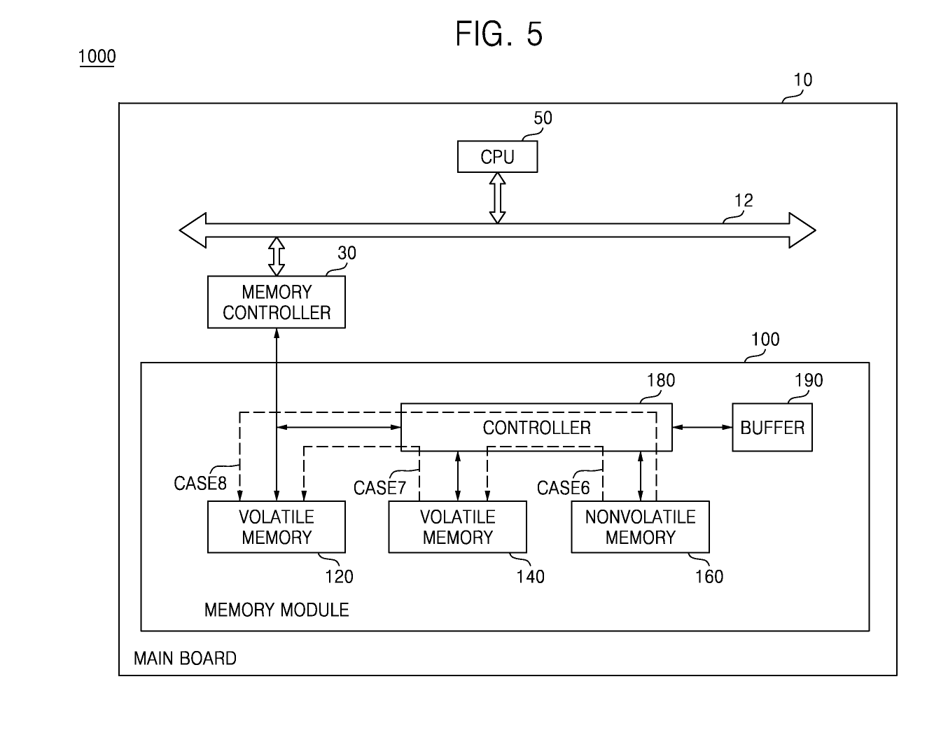

FIG. 5 is a diagram for explaining a restore operation of the memory system 1000 illustrated in FIG. 1. Referring to FIG. 5, when the power supply to the memory system 1000 is abnormally cut off, data stored in the first and second volatile memories 120 and 140 are lost.

When the memory system 1000 is rebooted, the CPU 50 may output a restore command. The restore command is transmitted to the controller 180 via the memory controller 30. The controller 180 performs the restore operation in response to the restore command.

During the restore operation, the controller 180 may read data from the nonvolatile memory 160 and may write the data to the second volatile memory 140 (CASE6).

In addition, the controller 180 may read the data from the second volatile memory 140 and may write the data to the first volatile memory 120 (CASE7). Accordingly, data that have been lost from the first volatile memory 120 due to abnormal cut-off of the power supply can be restored.

Alternatively, the controller 180 may perform the restore operation by reading data from the nonvolatile memory 160 and by writing the data directly to the first volatile memory 120 (CASES).

Thus, in accordance with embodiments of the inventive concept, a robust and fault-tolerant memory system is provided.

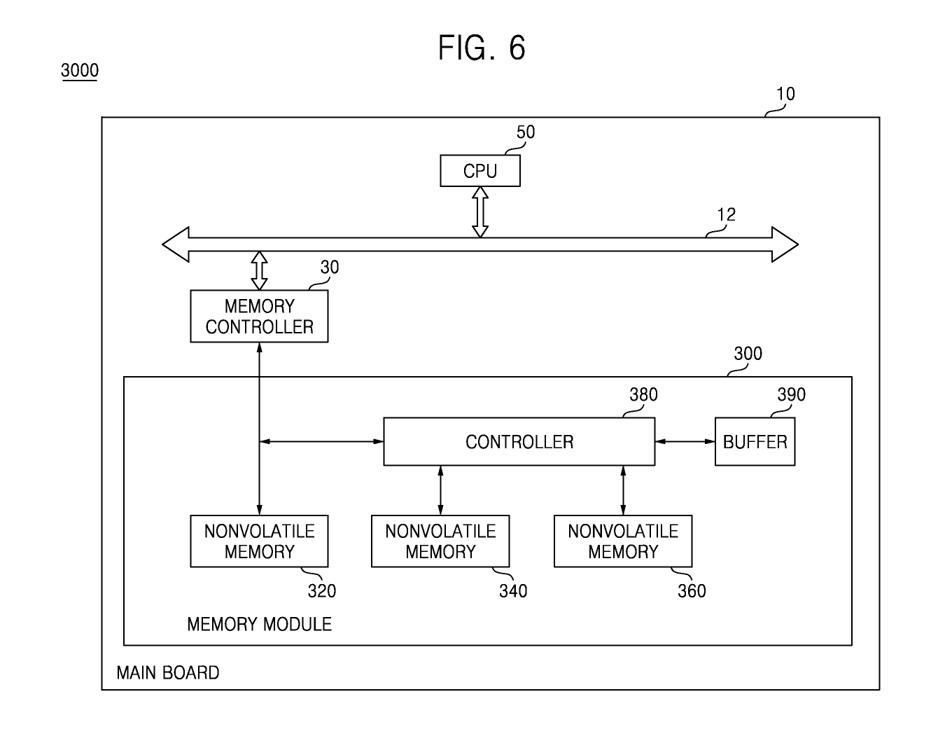

FIG. 6 is a block diagram of a memory system 3000 according to other embodiments of the inventive concept. Referring to FIG. 6, the memory system 3000 includes the main board 10, a memory module 300, the memory controller 30, and the CPU 50.

The structure illustrated in FIG. 6 is substantially the same as that illustrated in FIG. 1, with the exception that volatile memories are replaced with nonvolatile memories and the memory module's and its components' reference numerals are changed. Therefore, detailed descriptions of the alike structures will be omitted for the sake of brevity.

The memory controller 30 may be mounted to the main board 10. The memory controller 30 may control the operation of the memory module 300 according to the control of the CPU 50. In a write operation, the memory controller 30 may output a write command, a write address, and write data. In a read operation, the memory controller 30 may output a read command and a read address. Here, the write address and the read address are addresses in a first nonvolatile memory 320 included in the memory module 300.

The CPU 50 may be mounted to the main board 10 and may control the operation of the memory module 300 via the memory controller 30. The CPU 50 and the memory controller 30 may communicate with each other through the data/address/command bus 12.

The memory module 300 may be connected to the main board 10 via a slot or a memory socket provided in, e.g. built into, the main board 10. The memory module 300 includes the first nonvolatile memory 320, a second nonvolatile memory 340, a third nonvolatile memory 360, and a controller 380. According to some embodiments, the memory module 300 may also include a buffer 390.

The first nonvolatile memory 320 included in the memory module 300 may be used as a main memory of the memory system 3000. In the write operation, the first nonvolatile memory 320 may receive the write data and may write them to the storage area corresponding to the write address based on the write command and the write address, which are provided by the memory controller 30. In the read operation, the first nonvolatile memory 320 may read data from a storage area corresponding to the read address based on the read command and the read address, which are provided by the memory controller 30.

Each of the first and second nonvolatile memories 320 and 340 may be implemented by ferroelectric RAM (FeRAM), PRAM, MRAM, and/or STT-MRAM, or the like.

When the first and second nonvolatile memories 320 and 340, respectively, are implemented by the same types of memories, the access speed of the first nonvolatile memory 320 is the same or substantially the same as that of the second nonvolatile memory 340. Accordingly, performance deterioration that may occur in the first nonvolatile memory 320, i.e., the main memory, when the first and second nonvolatile memories 320 and 340 have difference access speeds can be minimized or prevented. Here, the access speed may refer to a read speed or a write speed.

The third nonvolatile memory 360 may be implemented by flash memory, e.g., NOR flash memory, NAND flash memory, or the like.

For instance, when the first and second nonvolatile memories 320 and 340 are STT-MRAM that can process (e.g., write or read) data using a first data processing method, e.g., using magnetic resistance, the third nonvolatile memory 360 may be implemented by flash memory that can process (e.g., program or erase) data using a second data processing method, e.g., using Fowler-Nordheim (F-N) tunneling.

The controller 380 may control the operations of the second and third nonvolatile memories 340 and 360. In the write operation, the controller 380 receives the write command, the write address, and the write data from the memory controller 30 and outputs them to the second nonvolatile memory 340. The second nonvolatile memory 340 may receive the write command, the write address, and the write data and may write the write data and the write address to the storage area. Accordingly, the address of the storage area of the first nonvolatile memory 320 in which the write data are stored is written to the second nonvolatile memory 340 together with the write data.

The controller 380 may perform a backup operation by reading the write address and the write data stored from the second nonvolatile memory 340 and by writing the write address and the write data, which have been read, to the third nonvolatile memory 360.

When new data are output from the memory controller 30 during the backup operation, the controller 380 may store the new data in the buffer 390 and, after finishing the backup operation, write the data stored in the buffer 390 to the second nonvolatile memory 340. The controller 380 may also perform one or more subsequent backup operations, which may include, for example, reading the new data from the second nonvolatile memory 340 and writing the new data to the third nonvolatile memory 360.

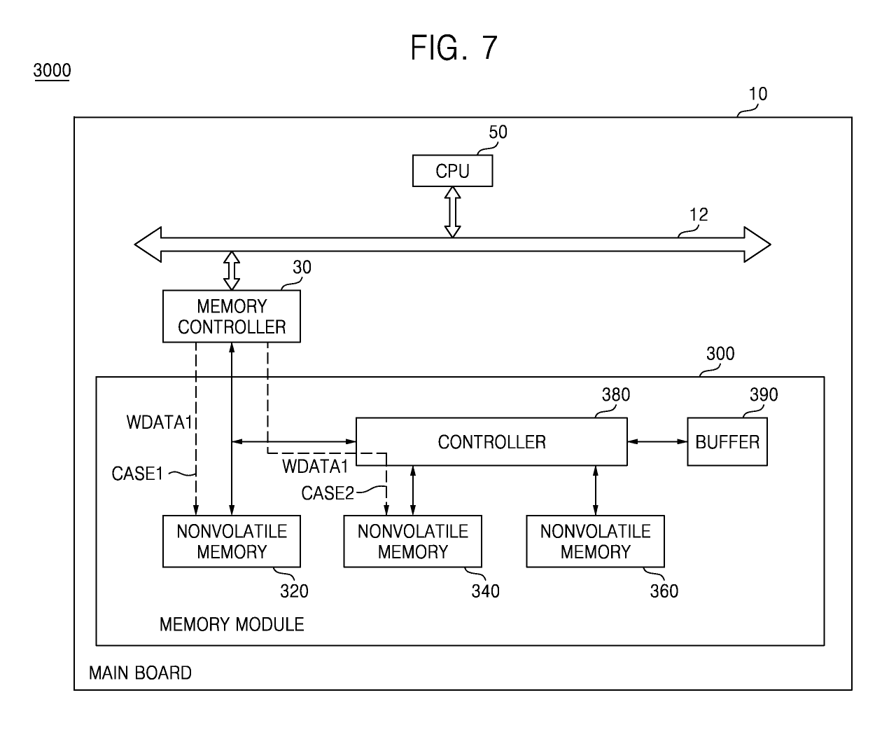

FIG. 7 is a diagram for explaining a write operation of the memory system 3000 illustrated in FIG. 6. Referring to FIG. 7, in the write operation, the memory controller 30 outputs a first write command, a first write address, and first write data WDATA1 under the control of the CPU 50.

The first nonvolatile memory 320 may receive the first write command, the first write address, and the first write data WDATA1 from the memory controller 30 and may write the first write data WDATA1 to a first storage area corresponding to the first write address (CASE1).

In addition, the controller 380 may receive the first write command, the first write address, and the first write data WDATA1 output from the memory controller 30 and may write the first write address and/or the first write data WDATA1 to a second storage area of the second nonvolatile memory 340 (CASE2). The write operations associated with CASE1 and CASE2 may occur simultaneously or at about the same time. In some embodiments, the first write address is the same as or otherwise corresponds to the address of the first storage area in which the first write data WDATA1 are stored, which may also correspond to the address of the second storage area in which the first write data WDATA1 and/or the first write address are stored. Alternatively, since both the first write data WDATA1 and the first write address can be stored in the second storage area of the nonvolatile memory 340, the first write data WDATA1 need not necessarily be stored at a location specifically corresponding to the first write address. Instead, the first write data WDATA1 may be stored at a different (i.e., second) write address within the nonvolatile memory 340.

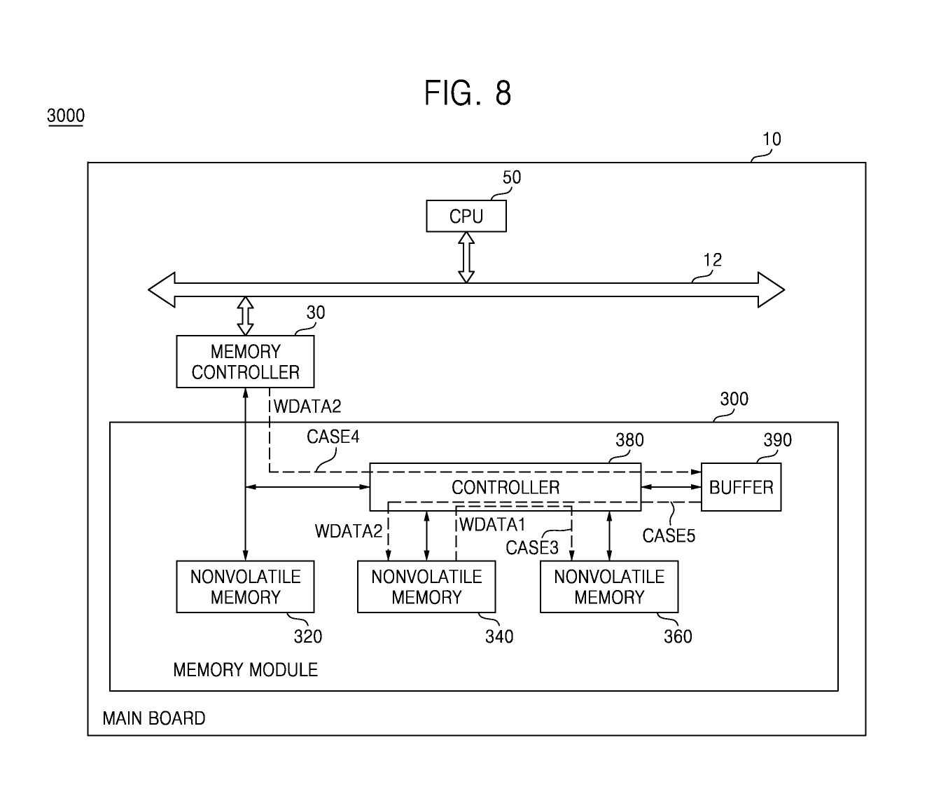

FIG. 8 is a diagram for explaining a backup operation of the memory system 3000 illustrated in FIG. 6. Referring to FIGS. 7 and 8, the controller 380 performs the backup operation in which the data WDATA1 stored in the second nonvolatile memory 340 are backed up to the third nonvolatile memory 360 (CASES). In other words, the first write address and/or the first write data WDATA1 previously written to the second nonvolatile memory 340 may be written to the third nonvolatile memory 360, under the control of the controller 380.

The controller 380 may read the first write address and/or the first write data WDATA1 from the second nonvolatile memory 340 and may write the first write address and/or the first write data WDATA1, which have been read by the controller 380, to the third nonvolatile memory 360. At about this time, the first write address and the first write data WDATA1 stored in the second nonvolatile memory 340 may be erased under the control of the controller 380. Accordingly, the size of the second nonvolatile memory 340 may be smaller than that of the first nonvolatile memory 320, which reduces the cost of the components of the memory system 3000, while still maintaining a suitably expansive and highly fault tolerant system.

The backup operation may be performed periodically. In other words, the controller 380 may perform the backup operation at predetermined time intervals. Alternatively, the backup operation may be triggered by one or more events, such as by a write operation, a series of predetermined write operations, a read operation, a series of predetermined read operations, a message from the memory controller 30, or the like.

When a second write command, a second write address, and second write data WDATA2 are output from the memory controller 30 while the controller 380 is performing the backup operation, the first nonvolatile memory 320 writes the second write data WDATA2 to a storage area corresponding to the second write address in response to the second write command.

Meanwhile, since the backup operation is in progress, the controller 380 cannot write the second write data WDATA2 to the second nonvolatile memory 340. In this case, the controller 380 may store the second write command, the second write address, and the second write data WDATA2, which are output from the memory controller 30, in the buffer 390 (CASE4).

After the first write address and the first write data WDATA1 are erased from the second nonvolatile memory 340, under the control of the controller 380, the controller 380 may write the second write address and the second write data WDATA2 stored in the buffer 390 to the second nonvolatile memory 340 (CASES).

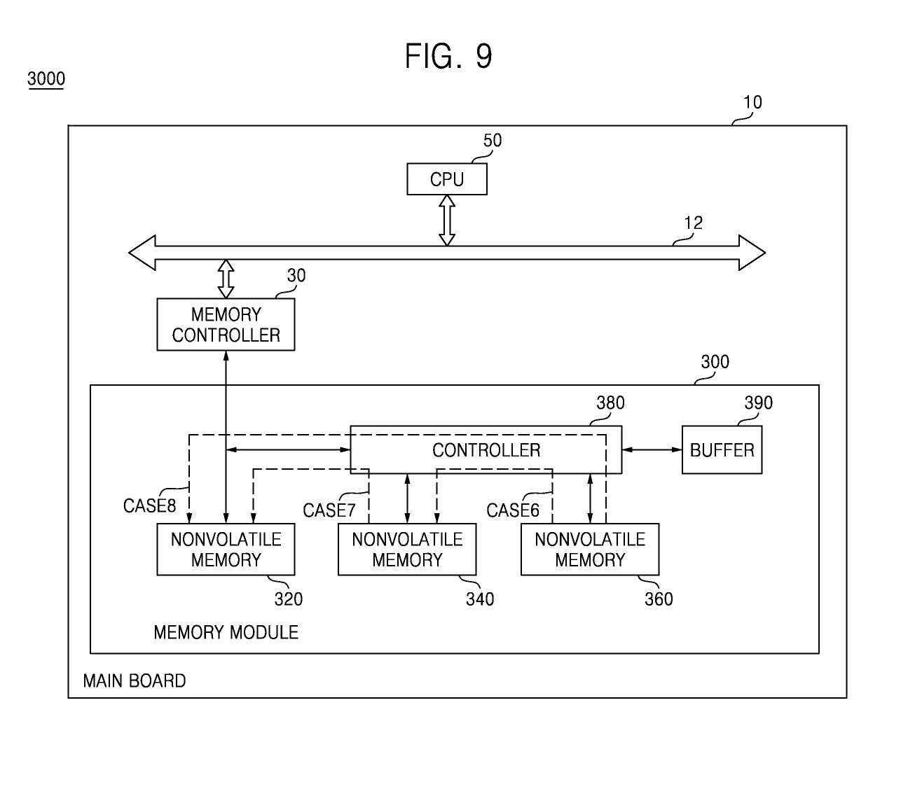

FIG. 9 is a diagram for explaining a restore operation of the memory system 3000 illustrated in FIG. 6. Referring to FIG. 9, when the memory system 3000 is rebooted after the power supply to the memory system 3000 is abnormally cut off, the CPU 50 may output a restore command. The restore command is transmitted to the controller 380 via the memory controller 30. The controller 380 performs the restore operation in response to the restore command.

During the restore operation, the controller 380 may read data from the third nonvolatile memory 360 and may write the data to the second nonvolatile memory 340 (CASE6). In addition, the controller 380 may read the data from the second nonvolatile memory 340 and may write the data to the first nonvolatile memory 320 (CASE7). Since both the write data and the write address were previously stored in the second nonvolatile memory 340 and/or the third nonvolatile memory 360, the data can be restored to the appropriate location in the first nonvolatile memory 320. Accordingly, data that have been lost from the first nonvolatile memory 320 due to abnormal cut-off of the power supply can be restored in accordance with the restore operation described and illustrated herein.

Alternatively, the controller 380 may perform the restore operation by reading data from the third nonvolatile memory 360 and by writing the data directly to the first nonvolatile memory 320 (CASES).

As described above, when the memory system 3000 is rebooted, data in the first nonvolatile memory 320 are restored based on data in the second nonvolatile memory 340 and/or the third nonvolatile memory 360. Therefore, any errors in the data stored in the first nonvolatile memory 320 before the memory system 3000 is rebooted can be restored to a proper value or otherwise corrected. Moreover, any errors in the data stored in the first nonvolatile memory 320 as a result of the abnormal cut off of power can be restored to a proper value or otherwise corrected.

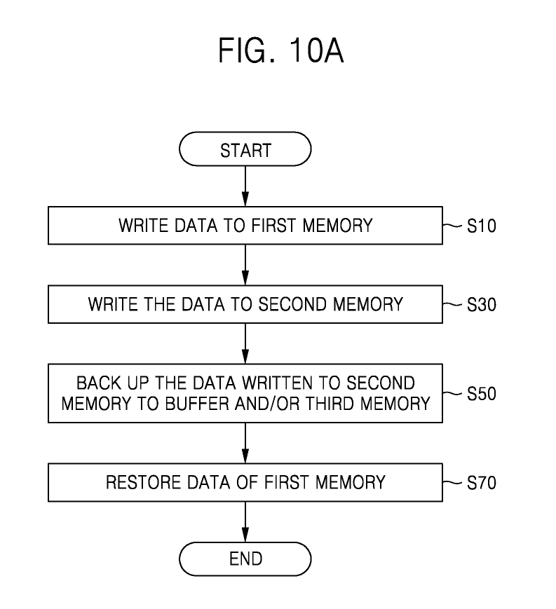

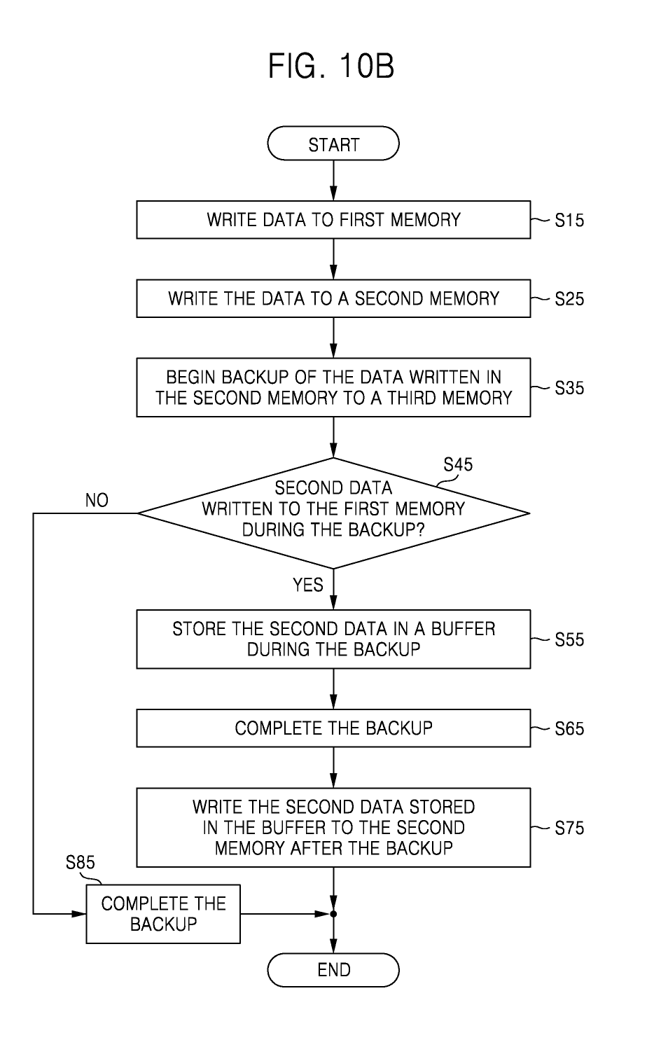

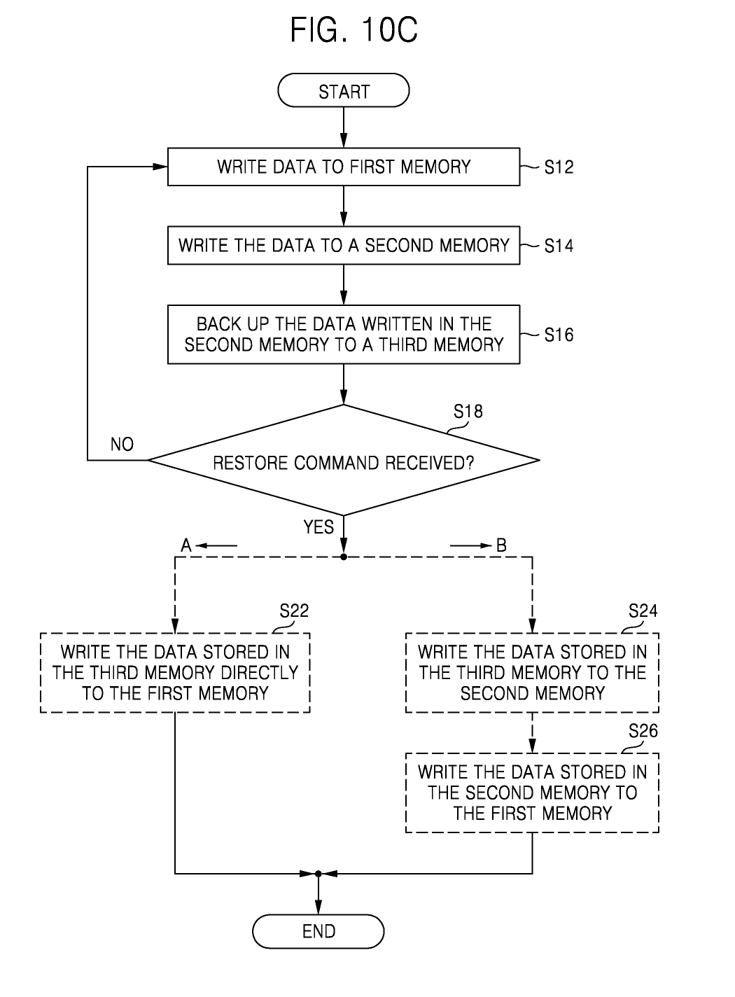

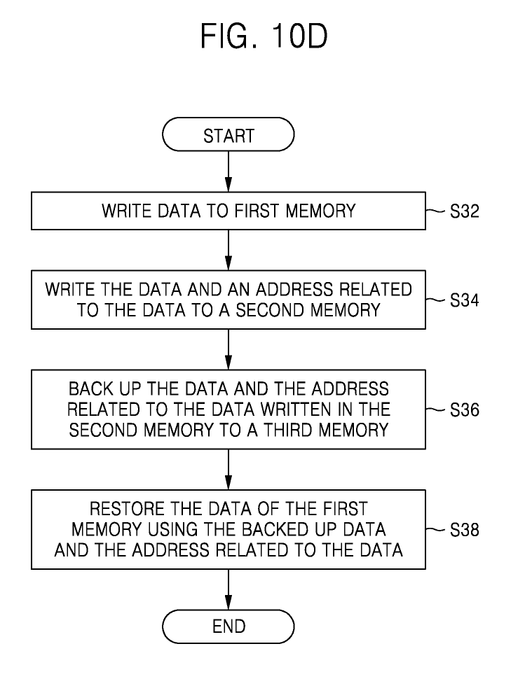

FIG. 10A is a flowchart of a technique of operating the memory system 1000 or 3000 illustrated in FIG. 1 or 6 according to some embodiments of the inventive concept. Referring to FIGS. 1 through 10A, the memory controller 30 may write first write data to a first memory under the control of the CPU 50 in operation S10. In other words, the first memory may write the first write data in a first storage area corresponding to a first write address based on a first write command and the first write address, which are output from the memory controller 30.

The controller 180 or 380 may receive the first write command, the first write address, and the first write data from the memory controller 30 and write the first write data to a second storage area corresponding to the first write address in operation S30. The second storage area is a storage area corresponding to the first write address in a second memory.

The controller 180 or 380 may back up the data stored in the second memory to a third memory in operation S50. The controller 180 or 380 may perform the backup operation periodically or in response to a predetermined event, as discussed above.

When a second write command, a second write address, and second write data are output from the memory controller 30 while the controller 180 or 380 is performing the backup operation, the controller 180 or 380 may store the second write command, the second write address, and the second write data in the buffer 190 or 390.

After finishing the backup operation, the controller 180 or 380 may write the second write data stored in the buffer 190 or 390 to the second memory.

Here, the first memory may be the first volatile memory 120 illustrated in FIG. 1 or the first nonvolatile memory 320 illustrated in FIG. 6. The second memory may be the second volatile memory 140 illustrated in FIG. 1 or the second nonvolatile memory 340 illustrated in FIG. 6. The third memory may be the nonvolatile memory 160 illustrated in FIG. 1 or the third nonvolatile memory 360 illustrated in FIG. 6.

When the memory system 1000 or 3000 is rebooted, the controller 180 or 380 may restore the data of the first memory under the control of the CPU 50 or the memory controller 30 in operation S70. In other words, the controller 180 or 380 may receive a restore command from the CPU 50 via the memory controller 50 and may perform a restore operation in response to the restore command.

More specifically, the controller 180 or 380 may read data from the third memory and write the data to the second memory. In addition, the controller 180 or 380 may read the written data from the second memory and may write the data read from the second memory to the first memory.

Alternatively, the controller 180 or 380 may perform the restore operation by reading data from the third memory and writing the read data directly to the first memory.

FIG. 10B is a flowchart of a technique of operating the memory system 1000 or 3000 illustrated in FIG. 1 or 6 according to some embodiments of the inventive concept. Referring to FIGS. 1 through 10B, the memory controller 30 may write first write data to a first memory under the control of the CPU 50 in operation S15. In other words, the first memory may write the first write data in a first storage area corresponding to a first write address based on a first write command and the first write address, which are output from the memory controller 30.

The controller 180 or 380 may receive the first write command, the first write address, and the first write data from the memory controller 30 and write the first write data to a second storage area, which may correspond to the first write address, in operation S25. The second storage area may be a storage area corresponding to the first write address in a second memory.

The controller 180 or 380 may begin backing up the data stored in the second memory to a third memory in operation S35. The controller 180 or 380 may perform the backup operation periodically or in response to a predetermined event, as discussed above.

At operation S45, it is determined whether a second write command, a second write address, and second write data are output from the memory controller 30 while the controller 180 or 380 is performing the backup operation. If YES, the controller 180 or 380 may store the second write command, the second write address, and/or the second write data in the buffer 190 or 390 during the backup at operation S55.

After finishing the backup operation at S65, the controller 180 or 380 may write the second write data stored in the buffer 190 or 390 to the second memory at S75.

Otherwise, if the determination at S45 is NO, then the flow proceeds to operation S85, where the backup operation is completed.

Here, the first memory may be the first volatile memory 120 illustrated in FIG. 1 or the first nonvolatile memory 320 illustrated in FIG. 6. The second memory may be the second volatile memory 140 illustrated in FIG. 1 or the second nonvolatile memory 340 illustrated in FIG. 6. The third memory may be the nonvolatile memory 160 illustrated in FIG. 1 or the third nonvolatile memory 360 illustrated in FIG. 6.

FIG. 10C is a flowchart of a technique of operating the memory system 1000 or 3000 illustrated in FIG. 1 or 6 according to some embodiments of the inventive concept. Referring to FIGS. 1 through 10C, the memory controller 30 may write first write data to a first memory under the control of the CPU 50 in operation S12. In other words, the first memory may write the first write data in a first storage area corresponding to a first write address based on a first write command and the first write address, which are output from the memory controller 30.

The controller 180 or 380 may receive the first write command, the first write address, and the first write data from the memory controller 30 and write the first write data to a second storage area, which may correspond to the first write address in operation S14. The second storage area may be a storage area corresponding to the first write address in a second memory.

The controller 180 or 380 may back up the data stored in the second memory to a third memory in operation S16. The controller 180 or 380 may perform the backup operation periodically or in response to a predetermined event, as discussed above.

Here, the first memory may be the first volatile memory 120 illustrated in FIG. 1 or the first nonvolatile memory 320 illustrated in FIG. 6. The second memory may be the second volatile memory 140 illustrated in FIG. 1 or the second nonvolatile memory 340 illustrated in FIG. 6. The third memory may be the nonvolatile memory 160 illustrated in FIG. 1 or the third nonvolatile memory 360 illustrated in FIG. 6.

At S18, a determination is made whether a restore command is received. The restore command can be generated, for example, in response to the memory system 1000 or 3000 being rebooted. If the determination is YES, then either path A or path B can be taken. In either case, the controller 180 or 380 may restore the data of the first memory under the control of the CPU 50 or the memory controller 30 in operations S22, S24, and/or S26. In other words, the controller 180 or 380 may receive a restore command from the CPU 50 via the memory controller 50 and may perform a restore operation in response to the restore command.

More specifically, if path B is taken, the controller 180 or 380 may read data from the third memory and may write the data to the second memory at operation S24. In addition, the controller 180 or 380 may read the written data from the second memory and write the data read from the second memory to the first memory at operation S26.

Alternatively, if path A is taken, the controller 180 or 380 may perform the restore operation by reading data from the third memory and writing the read data directly to the first memory at operation S22.

FIG. 10D is a flowchart of a technique of operating the memory system 1000 or 3000 illustrated in FIG. 1 or 6 according to some embodiments of the inventive concept. Referring to FIGS. 1 through 10D, the memory controller 30 may write first write data to a first memory under the control of the CPU 50 in operation S32. In other words, the first memory may write the first write data in a first storage area corresponding to a first write address based on a first write command and the first write address, which are output from the memory controller 30.

The controller 180 or 380 may receive the first write command, the first write address, and the first write data from the memory controller 30 and may write the first write data and the first write address to a second storage area in operation S34. The second storage area is in a second memory, but the second storage area need not correspond to the first write address because the first write address itself is also stored in the second memory.

The controller 180 or 380 may back up the data, including the first write data and the related address, stored in the second memory to a third memory in operation S36. The controller 180 or 380 may perform the backup operation periodically or in response to a predetermined event, as discussed above.

When the memory system 1000 or 3000 is rebooted, the controller 180 or 380 may restore the data of the first memory under the control of the CPU 50 or the memory controller 30 in operation S38. For example, the controller 180 or 380 may receive a restore command from the CPU 50 via the memory controller 50 and may perform a restore operation in response to the restore command.

More specifically, the controller 180 or 380 may read data and the related address from the third memory and may write the data and the related address to the second memory. In addition, the controller 180 or 380 may read the written data and related address from the second memory and may write the data read from the second memory to the first memory at the location corresponding to the address related to the data.

Alternatively, the controller 180 or 380 may perform the restore operation by reading data from the third memory and by writing the read data directly to the first memory at the location corresponding to the address related to the data.

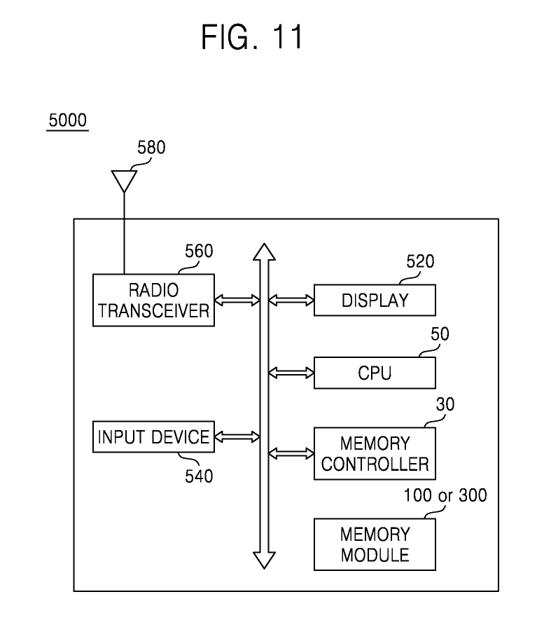

FIG. 11 is a block diagram of a memory system 5000 according to further embodiments of the inventive concept. Referring to FIGS. 1, 6 and 11, the memory system 5000 may be implemented as a mobile phone, smart phone, tablet PC, computing system and/or a wireless Internet system, or the like.

The memory system 5000 includes the memory module 100 or 300, the CPU 50 controlling the data processing operations of the memory module 100 or 300, and the memory controller 30. As discussed in detail above, the memory controller 30 is for controlling the data access operations, e.g., a write operation and a read operation, on the memory module 100 or 300 under the control of the CPU 50.

Data stored in the first volatile memory 120 included in the memory module 100 or in the first nonvolatile memory 320 included in the memory module 300 may be displayed on a display 520 under the control of the CPU 50 and/or the memory controller 30.

A radio transceiver 560 may transmit or receive radio signals through an antenna 580. The radio transceiver 560 may convert radio signals received through the antenna 580 into signals that can be processed by the CPU 50.

Accordingly, the CPU 50 may process the signals output from the radio transceiver 560 and may store the processed signals in the first volatile memory 120 or the first nonvolatile memory 320 through the memory controller 30, or may otherwise usefully process and utilize the signals, e.g. it may display the signals on the display 520.

The radio transceiver 560 may also convert signals output from the CPU 50 into radio signals and may output the radio signals to an external device through the antenna 580.

An input device 540 enables control signals for controlling the operation of the CPU 50 or data to be processed by the CPU 50 to be input to the memory system 5000. The input device 540 may be implemented by a pointing device such as a touch pad or computer mouse, keypad, and/or keyboard, or the like.

The CPU 50 may control the operation of the display 520 to display data output from the first volatile memory 120 or from the first nonvolatile memory 320, data output from the radio transceiver 560, and/or data output from the input device 540.

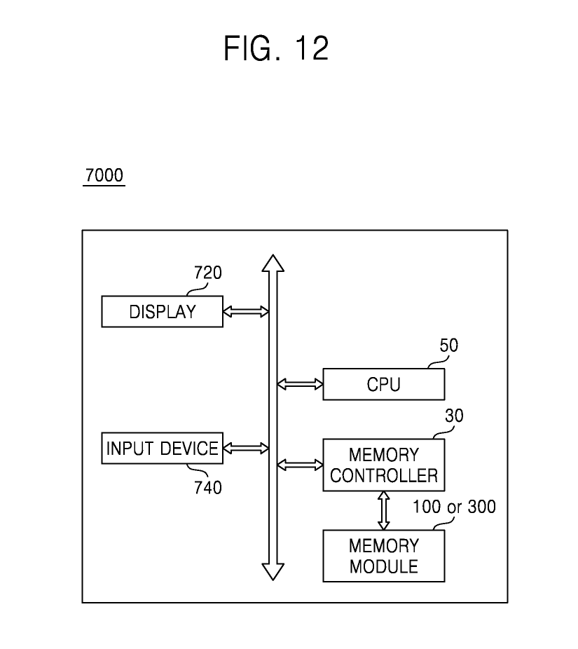

FIG. 12 is a block diagram of a memory system 7000 according to other embodiments of the inventive concept. Referring to FIG. 12, the memory system 7000 may be implemented as a data processing device such as a tablet PC, net-book, e-reader, PDA, PMP, MP3 player, and/or MP4 player, or the like.

The memory system 7000 includes the memory module 100 or 300 and the CPU 50 controlling the data processing operations of the memory module 100 or 300.

The CPU 50 may display data stored in the first volatile memory 120 included in the memory module 100 or may display data stored in the first nonvolatile memory 320 included in the memory module 300 on a display 720 according to an input signal generated by an input device 740.

The memory controller 30 may control the data access operations on the first volatile memory 120 or on the first nonvolatile memory 320 under the control of the CPU 50. The input device 740 may be implemented by a pointing device such as a touch pad, computer mouse, keypad, and/or keyboard, or the like.

As described above, according to some embodiments of the inventive concept, a memory module backs up data stored in a main memory to a nonvolatile memory, thereby enabling the data of the main memory to be restored based on the data backed up to the nonvolatile memory.

While example embodiments have been particularly shown and described with reference to example embodiments thereof, it will be understood by those of ordinary skill in the art that various changes in forms and details may be made therein without departing from the spirit and scope of example embodiments as defined by the following claims.

What is claimed is:

1. A memory module comprising:
a first volatile memory;
a second volatile memory;
a nonvolatile memory; and
a first controller configured to control an operation of the second volatile memory and an operation of the nonvolatile memory,
wherein when first data received from a second external controller is written to the first volatile memory in a write operation, the first controller is configured to receive and write the first data to the second volatile memory.

2. The memory module of claim 1, wherein the first data is stored in a first storage area of the first volatile memory and in a second storage area of the second volatile memory, wherein the first storage area is designated by a write address and the second storage area is designated by the write address.

3. The memory module of claim 1, wherein the first controller is configured to back up the first data stored in the second volatile memory to the nonvolatile memory.

4. The memory module of claim 3, further comprising a buffer,
wherein the first controller is configured to store second data output from the second external controller in the buffer while the first data stored in the second volatile memory is backed up to the nonvolatile memory, and
the first controller is configured to write the second data stored in the buffer to the second volatile memory after the backup is completed.

5. The memory module of claim 1, wherein the first volatile memory and the second volatile memory are dynamic random access memory (DRAM).

6. A board assembly comprising:
the memory module of claim 1; and
a main board,
wherein the memory module is configured to be mounted to the main board through a slot provided in the main board.

7. The board assembly of claim 6, wherein the first data are stored in a first storage area of the first volatile memory and in a second storage area of the second volatile memory, wherein the first storage area is designated by a write address and the second storage area is designated by the write address.

8. A memory system comprising:
the board assembly of claim 6, wherein the second external controller is a memory controller mounted to the main board; and
a processor configured to be mounted to the main board and to control an operation of the first volatile memory included in the memory module using the memory controller mounted to the main board.

9. The memory system of claim 8, wherein the memory module further comprises a buffer,
the first controller is configured to back up the first data stored in the second volatile memory to the nonvolatile memory,
the first controller is configured to store second data output from the second external controller in the buffer while the first controller is configured to back up the first data stored in the second volatile memory to the nonvolatile memory, and
the first controller is configured to write the second data stored in the buffer to the second volatile memory after the backup is completed.

10. A memory module comprising:
a first nonvolatile memory and a second nonvolatile memory configured to process first data;
a third nonvolatile memory configured to back up the first data; and
a first controller configured to control a write operation of the second nonvolatile memory and the backup operation of the third nonvolatile memory,
wherein when first data received from a second external controller is written to the first nonvolatile memory in a write operation, the first controller is configured to receive and write the first data to the second nonvolatile memory.

11. The memory module of claim 10, wherein the first controller is configured to write the first data written to the first nonvolatile memory and an address related to the first data to the second nonvolatile memory.

12. The memory module of claim 11, wherein the first controller is configured to back up the first data and the address, which are stored in the second nonvolatile memory, to the third nonvolatile memory, and wherein the first controller is configured to erase the first data and the address from the second nonvolatile memory.

13. The memory module of claim 11, further comprising a buffer,
wherein the first controller is configured to store second data output from the second external controller in the buffer while the first controller is configured to back up the first data and the address stored in the second nonvolatile memory to the third nonvolatile memory, and wherein
the first controller is configured to write the second data stored in the buffer to the second nonvolatile memory after the backup is completed.

14. A method of operating a memory system, the method comprising:
writing data to a first memory under the control of a first memory controller;
writing, by a second controller, the data output from the first memory controller to a second memory;
backing up, by the second controller, the data written to the second memory to a third memory; and
restoring, by the second controller, the data of the first memory based on the data backed up to the third memory when the memory system is rebooted.

15. The method of claim 14, wherein backing up the data further comprises:
storing, by the second controller, new data output from the first memory controller in a buffer during the backup; and
writing, by the second controller, the data stored in the buffer to the second memory after the backup.

16. The method of claim 14, wherein restoring the data further comprises:
writing, by the second controller, the data stored in the third memory to the second memory after the backup; and
writing, by the second controller, the data stored in the second memory to the first memory after the backup.

17. The method of claim 14, wherein restoring the data further comprises:
writing, by the second controller, the data stored in the third memory directly to the first memory after the backup.

18. The method of claim 14, wherein backing up the data further comprises:
storing, by the second controller, new data output from the first memory controller in a buffer during the backup;
writing, by the second controller, the new data stored in the buffer to the second memory after the backup; and
storing, by the second controller, the new data stored in the second memory in the third memory.

19. The method of claim 14, wherein the first memory is a volatile memory, the second memory is a volatile memory, and the third memory is a nonvolatile memory.

20. The method of claim 14, wherein the first memory is a nonvolatile memory, the second memory is a nonvolatile memory, and the third memory is a nonvolatile memory.
